(19) United States
(12) Patent Application Publication
(10) Pub. No.: US 2024/0418794 A1
(43) Pub. Date: Dec. 19, 2024

(54) BATTERY MONITORING DEVICE

(71) Applicant: Nuvoton Technology Corporation Japan, Kyoto (JP)

(72) Inventors: Tomohiro OKACHI, Kyoto (JP); Hitoshi KOBAYASHI, Osaka (JP); Keiichi FUJII, Shiga (JP); Susumu YOSHIKAWA, Shiga (JP)

(21) Appl. No.: 18/819,646

(22) Filed: Aug. 29, 2024

Related U.S. Application Data
(63) Continuation of application No. PCT/JP2023/008350, filed on Mar. 6, 2023.
(60) Provisional application No. 63/317,226, filed on Mar. 7, 2022.

(51) Int. Cl. G01R 31/392; G01R 31/374; G01R 31/3842; G01R 31/389

(52) U.S. Cl. CPC G01R 31/392; G01R 31/374; G01R 31/3842; G01R 31/389

(57) ABSTRACT

A battery monitoring device includes a measurement unit and a calculation unit. The measurement unit includes a voltage measurement unit and a current measurement unit. The calculation unit includes: storage that holds first relationship data indicating a relationship between SOC and OCV and second relationship data indicating a relationship between impedance and SOH; an impedance calculation unit that identifies a low current interval, sets a voltage obtained during the low current interval as a provisional OCV, and calculates an impedance of secondary cells from a voltage value and a current value in a transient current response; an SOH estimate unit that estimates an SOH by referencing the second relationship data using the impedance; and an SOC estimate unit that estimates an SOC by referencing the first relationship data based on the provisional OCV.

### CROSS REFERENCE TO RELATED APPLICATIONS

This is a continuation application of PCT International Application No. PCT/JP2023/008350 filed on Mar. 6, 2023, designating the United States of America, which is based on and claims priority of U.S. Provisional Patent Application No. 63/317,226 filed on Mar. 7, 2022. The entire disclosures of the above-identified applications, including the specifications, drawings, and claims are incorporated herein by reference in their entirety.

### FIELD

The present disclosure relates to a battery monitoring device, and more specifically, to a technique for estimating a degradation state of a secondary cell such as a lithium-ion secondary cell.

### BACKGROUND

In recent years, applications that use secondary cells (hereinafter also simply referred to as “cells”) in battery-equipped devices such as vehicles, electric storage devices, stationary power supply devices, automated guided vehicles (AGVs), robots, and drones have been increasing rapidly. Lithium-ion secondary cells (also referred to as lithium-ion batteries (LiB)) are often adopted for such applications due to their high energy density. Many on-board batteries and storage batteries are configured as a cell stack in which cells are arranged side by side and connected in series or parallel. When lithium-ion secondary cells are used, known issues include accelerated degradation due to overcharge, overdischarge or temperature, and in the worst cases, this may lead to dangerous conditions such as smoke emission, ignition, and even explosion. Therefore, a battery monitoring device (also referred to as a battery management system (BMS)) is typically included and appropriately controlled.

As an example of such a conventional BMS, Patent Literature (PTL) 1 discloses, as a battery monitoring device capable of monitoring the state of a cell, a technique of monitoring the voltages, currents, and temperatures of all secondary cells of a cell stack, and using the measured data to monitor the state of each cell.

Secondary cells as described above degrade over long-term use due to changes in internal state and other factors from the start of use.

Therefore, the battery monitoring device periodically estimates the internal state of the cell stack and the like to diagnose the degradation states of the secondary cells. For example, methods for diagnosing the degradation state of a secondary cell include measuring the internal resistance of the secondary cell via the AC impedance measurement technique disclosed in PTL 2 and via the direct current resistance measurement technique disclosed in PTL 3. In these techniques, the degradation state of a secondary cell is determined by confirming the behavior of the internal resistance and the correlation between the state of charge (SOC) and the state of health (SOH).

### CITATION LIST

### Patent Literature

PTL 1: Japanese Patent No. 5403437
PTL 2: Japanese Patent No. 6842212
PTL 3: Japanese Unexamined Patent Application Publication No. 2009-288039

### SUMMARY

### Technical Problem

However, in applications that are constantly operating, such as automated guided vehicles, drones, cleaning robots, monitoring robots, etc., it is difficult to measure the impedance of the cells because the cells are in a state of constantly being charged and discharged, making it difficult to accurately grasp the SOC and the SOH.

In view of this, the present disclosure has an object to provide a battery monitoring device capable of accurately estimating the SOC and the SOH of secondary cells even in a case where the secondary cells are used in a state in which they are constantly being charged and discharged.

### Solution to Problem

In order to achieve the above-described object, a battery monitoring device according to one aspect of the present disclosure monitors a state of a cell stack including secondary cells connected in series or parallel, and includes: a measurement unit configured to measure a state of the secondary cells; and a calculation unit configured to calculate and estimate a state of charge (SOC) and a state of health (SOH) of the secondary cells based on the state of the secondary cells measured. The measurement unit includes: a voltage measurement unit configured to measure a voltage of the secondary cells; and a current measurement unit configured to measure current flowing through the secondary cells. The calculation unit includes: storage that holds at least first relationship data indicating a relationship between SOC and open circuit voltage (OCV) of the cell stack and second relationship data indicating a relationship between impedance and SOH of the cell stack; an impedance calculation unit configured to identify a low current interval during which current flowing through the secondary cells is less than or equal to a threshold value, identify a voltage obtained by the voltage measurement unit during the low current interval as a provisional OCV, and calculate an impedance of the secondary cells from the provisional OCV identified and from a voltage value obtained by the voltage measurement unit and a current value obtained by the current measurement unit in a transient current response; an SOH estimate unit configured to estimate the SOH of the secondary cells by referencing the second relationship data using the impedance obtained by the impedance calculation unit; and an SOC estimate unit configured to estimate the SOC of the secondary cells by referencing the first relationship data, based on the provisional OCV.

### Advantageous Effects

In view of this, the present disclosure has an object to provide a battery monitoring device capable of accurately estimating the SOC and the SOH of secondary cells even in a case where the secondary cells are used in a state in which they are constantly being charged and discharged.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a functional block diagram illustrating the configuration of a battery monitoring device according to an embodiment of the present disclosure.

FIG. 2 is a flowchart illustrating main operations performed by a battery monitoring device according to an embodiment of the present disclosure.

FIG. 3 is for explaining the relationship between operations performed by an AGV equipped with a battery monitoring device according to an embodiment of the present disclosure and operations performed by the battery monitoring device.

FIG. 4 is a flowchart illustrating detailed operations performed by a battery monitoring device according to an embodiment of the present disclosure.

FIG. 5 is a flowchart illustrating the procedures of step S30 (preparation of second relationship data) in FIG. 4 in greater detail.

FIG. 6 is a flowchart illustrating the procedures of step S31 (present SOH estimation) in FIG. 4 in greater detail.

FIG. 7 is a flowchart illustrating the procedures of step S32 (determination using the voltage difference between the first OCV and the initial OCV) in FIG. 4 in greater detail.

FIG. 8 illustrates an example of initial information of a cell stack.

FIG. 9 is for explaining an example of determination of a low current interval by a battery monitoring device (an example of using the number of investigations).

FIG. 10 is for explaining an example of determination of a low current interval by a battery monitoring device (an example of using the investigation time).

FIG. 11 is for explaining the method of calculating Warburg impedance by a battery monitoring device.

FIG. 12 illustrates the SOH dependency of a secondary cell.

FIG. 13 is for explaining second relationship data that indicates the relationship between impedance and SOH and is created using the secondary cell characteristics illustrated in FIG. 12.

FIG. 14 is for explaining the basis for calculating the present OCV from the provisional OCV using the total impedance of a secondary cell.

FIG. 15 is for explaining a method of updating the SOC-OCV correlation curve stored in storage.

FIG. 16 is for explaining an operation example of a drone equipped with a cell stack and a battery monitoring device.

FIG. 17 is for explaining an operation example of a cleaning robot equipped with a cell stack and a battery monitoring device.

FIG. 18 illustrates an example of communication between a battery monitoring device and an external storage device.

### DESCRIPTION OF EMBODIMENTS

Hereinafter, embodiments of the present disclosure will be described in detail with reference to the drawings. The embodiments described below each illustrate one specific example of the present disclosure. The numerical values, shapes, materials, elements, the arrangement and connection of the elements, steps, order of the steps, etc., shown in the following embodiments are mere examples, and therefore do not limit the scope of the present disclosure. Accordingly, among the elements in the following implementation examples, those not recited in any of the independent claims are described as optional elements.

The figures are schematic diagrams and are not necessarily precise illustrations. Elements that are essentially the same share the same reference signs in the figures, and duplicate description is omitted or simplified. The phrase “A and B are connected” means that A and B are electrically or communicably connected, and includes not only cases where A and B are directly connected, but also cases where A and B are indirectly connected with other circuit elements or communication devices interposed between A and B.

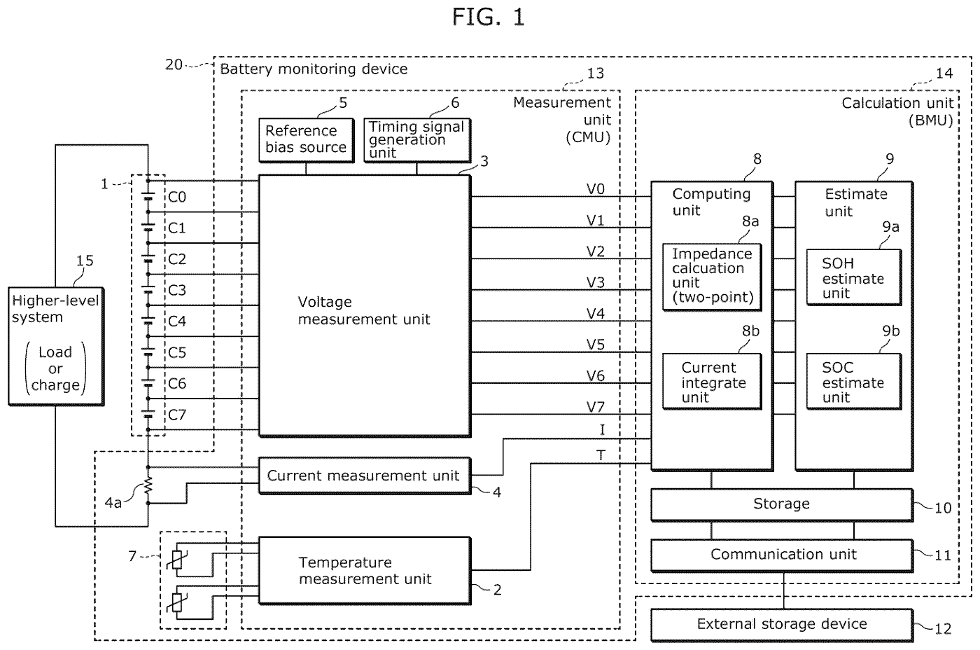

FIG. 1 is a functional block diagram illustrating the configuration of battery monitoring device 20 according to an embodiment of the present disclosure. FIG. 1 also illustrates cell stack 1 monitored by battery monitoring device 20, higher-level system (load unit and charger) 15 connected to cell stack 1, and external storage device 12 which is a communication partner.

Battery monitoring device 20, which is provided in a device such as an AGV, is a system that monitors the state of cell stack 1 including cells C0 to C7 (hereinafter also simply referred to as “cell Cn”) that are constantly charged and discharged, and includes thermistor 7, measurement unit (also referred to as a cell management unit (CMU)) 13, and calculation unit (also referred to as a battery management unit (BMU)) 14.

Cells C0 through C7 are connected in series or parallel to form cell stack 1, and are, specifically, lithium-ion secondary cells, but may be other types of secondary cells such as nickel metal hydride cells. Cell stack 1 functions as a power supply for the higher-level system (load unit and charger) 15, and supplies power to the higher-level system (load unit and charger) 15. Although cells C0 through C7 are exemplified as connected in series in the present embodiment, cells C0 through C7 are not limited to being connected in series and may be connected in parallel.

Measurement unit 13 mainly includes temperature measurement unit 2 that measures the temperature of cell stack 1, voltage measurement unit 3 that measures the voltages of cells C0 through C7, and current measurement unit 4 that measures the current flowing through cells C0 through C7.

Temperature measurement unit 2 measures temperature T of thermistor 7. Thermistor 7 is disposed at locations such as a terminal portion of cell stack 1 and portions of bus bars that connect cells C0 through C7 to each other in series or parallel. Thermistor 7 may be a temperature sensor that uses a different element such as a thermocouple.

Voltage measurement unit 3 measures voltages V0 through V7 of cells C0 through C7 in cell stack 1. Voltage measurement unit 3 includes, for example, AD converters. Timing signal generator 6 controls the measurement timings of currents measured by current measurement unit 4 and the measurement timings of voltages measured by voltage measurement unit 3. Reference bias source 5 provides a reference bias to the AD converters included in voltage measurement unit 3.

Current measurement unit 4 measures current I flowing through reference resistor (for example, a shunt resistor) 4a connected in series with cell stack 1. More specifically, current measurement unit 4 measures the current by measuring the voltage across the reference resistor. Current measurement unit 4 periodically measures the current even when the application that charges and discharges cell stack 1 is stopped or in a standby state.

Calculation unit 14 includes: computing unit 8 including impedance calculation unit 8a and current integrate unit 8b; estimate unit 9 including SOH estimate unit 9a and SOC estimate unit 9b; storage 10; and communication unit 11. Computing unit 8 and estimate unit 9 are implemented by a processor or the like that executes a program.

Storage 10 stores data that has been prepared in advance such as first relationship data indicating a relationship between SOC and open circuit voltage (OCV) of cell stack 1 (also referred to as a SOC-OCV correlation curve), and second relationship data indicating a relationship between Warburg impedance and SOH of cell stack 1 (also referred to as an impedance-SOH correlation table), as well as battery parameters such as the voltage, current, and temperature of cell stack 1 measured by measurement unit 13, the impedance calculated by computing unit 8, and the OCV, SOC, and SOH estimated by estimate unit 9. Here, “estimate” is synonymous with “calculate”.

Impedance calculation unit 8a identifies a low current interval during which current flowing through cells C0 through C7 is less than or equal to a threshold value, identifies a voltage obtained by voltage measurement unit 3 during the low current interval as a provisional OCV, and calculates various impedances (i.e., two-point impedances) of cells C0 through C7 including Warburg impedance and total impedance (i.e., internal impedance) from the identified provisional OCV and from the voltage values obtained by voltage measurement unit 3 and the current values obtained by current measurement unit 4 in a transient current response. Based on the temperature of cell stack 1 measured by temperature measurement unit 2, impedance calculation unit 8a performs correction to an impedance at a predetermined temperature (for example, 25° C.) by utilizing the fact that the internal resistance of a battery changes exponentially depending on the temperature.

To identify the low current interval, impedance calculation unit 8a uses one of two methods. In the first method, when a state in which the current values repeatedly obtained by current measurement unit 4 are (i) less than or equal to a threshold value and (ii) consistent within a predetermined range consecutively occurs a predetermined number of times or more, impedance calculation unit 8a identifies the duration that the state consecutively occurs as the low current interval. In the second method, when the current values repeatedly obtained by current measurement unit 4 remain less than or equal to a threshold value for a predetermined amount of time or longer, impedance calculation unit 8a identifies the duration during which the current values remain less than or equal to the threshold value as the low current interval. Here, for example, the duration during which the current flowing through cells C0 through C7 is less than or equal to 0.2 C is identified as the low current interval.

Current integrate unit 8b calculates an integrated value of current values by temporally integrating the current values of cells C0 through C7 measured by current measurement unit 4.

Using the impedances obtained by impedance calculation unit 8a, SOH estimate unit 9a estimates the SOH of cells C0 through C7 by referencing the second relationship data stored in storage 10. More specifically, SOH estimate unit 9a calculates the rate of increase of the Warburg impedance calculated by impedance calculation unit 8a with respect to the Warburg impedance of cells C0 through C7 in an initial state obtained in advance, and estimates the SOH by referencing the second relationship data using the calculated rate of increase.

Based on the provisional OCV, SOC estimate unit 9b estimates the SOC of cells C0 through C7 by referencing the first relationship data stored in storage 10. More specifically, SOC estimate unit 9b estimates the OCV of cells C0 through C7 as a first OCV using the provisional OCV, the impedances obtained by impedance calculation unit 8a, and the current values obtained by current measurement unit 4 in a transient current response, and estimates the SOC of cells C0 through C7 by referencing the first relationship data stored in storage 10 using the estimated first OCV.

SOC estimate unit 9b also references the first relationship data to identify, as an initial OCV, an OCV corresponding to an SOC obtained by subtracting the integrated value obtained by current integrate unit 8b from the SOC corresponding to the provisional OCV, and when the difference between the identified initial OCV and the first OCV is greater than or equal to a threshold value, updates the initial OCV in the first relationship data using the first OCV.

Communication unit 11 is a communication interface that communicates with external storage device 12 and is, for example, a near field communication (NFC) module or the like that wirelessly outputs cell parameters such as SOC and SOH stored in storage 10 to external storage device 12.

External storage device 12 stores cell parameters such as SOC and SOH output from battery monitoring device 20 via communication unit 11. The cell parameters such as SOC and SOH stored by external storage device 12 are, for example, read out by higher-level system 15 and utilized for control and monitoring of the charging and discharging of cell stack 1 by higher-level system 15. This inhibits overcharging and overdischarging of cell stack 1, making it possible to efficiently use cell stack 1 for a long time.

Although battery monitoring device 20 according to the present embodiment calculates the OCV, SOC, and SOH for each of cells C0 through C7 of cell stack 1 (i.e., on a per cell Cn basis), battery monitoring device 20 is not limited thereto, and may calculate the OCV, SOC, and SOH by regarding cell stack 1 as a single cell (i.e., on a per cell stack 1 basis).

Next, operations performed by battery monitoring device 20 according to the present embodiment configured as described above will be described.

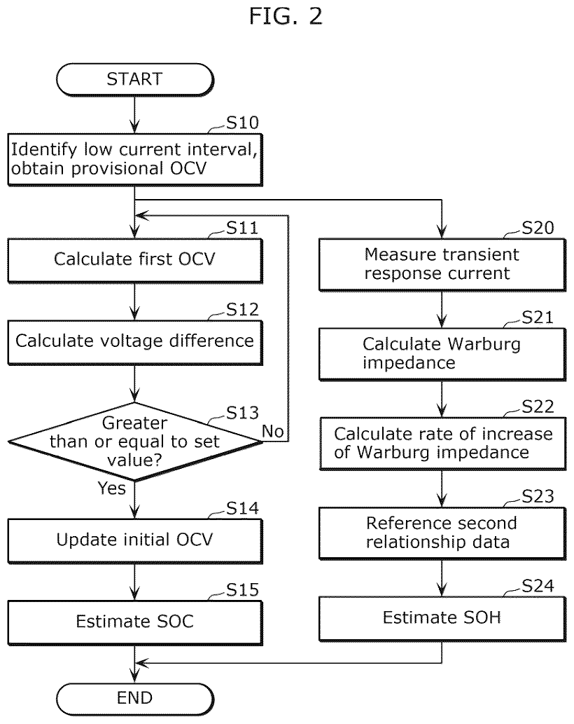

FIG. 2 is a flowchart illustrating main operations (i.e., estimation of SOC and SOH) performed by battery monitoring device 20 according to an embodiment of the present disclosure.

First, impedance calculation unit 8a identifies a low current interval during which current flowing through cells C0 through C7 is less than or equal to a threshold value, and obtains a voltage obtained by voltage measurement unit 3 in the low current interval as a provisional OCV (S10).

For each of cells C0 through C7, SOC estimate unit 9b performs the following processes (S11 through S15) to estimate the OCV and SOC of cell Cn. SOC estimate unit 9b calculates a first OCV, which is the provisional OCV corrected, using two voltages measured by voltage measurement unit 3 at the start and end of a charge/discharge interval (S11), calculates a voltage difference between the calculated first OCV and the initial OCV stored in storage 10 (S12), and determines whether the voltage difference is greater than or equal to a set value (for example, 10 mV) (S13).

As a result, when it is determined that the voltage difference is greater than or equal to the set value (Yes in S13), SOC estimate unit 9b updates the initial OCV stored in storage 10 by overwriting it with the first OCV (S14), references the first relationship data showing the relationship between SOC and OCV stored in storage 10 to identify the SOC corresponding to the first OCV, and estimates the identified SOC as the SOC of cell Cn (S15). When it is determined that the voltage difference is not greater than or equal to the set value (No in S13), SOC estimate unit 9b repeats steps S11 through S13.

After the low current interval and the provisional OCV are identified (S10), SOH estimate unit 9a performs the following processes (S20 through S24) for each of cells C0 through C7 to estimate the SOH of cell Cn. SOH estimate unit 9a measures a transient current response starting from a low current interval (S20), calculates a Warburg impedance from the transient current response (S21), calculates a rate of increase of the calculated Warburg impedance with respect to the Warburg impedance of cells C0 through C7 in an initial state obtained in advance (S22), and using the calculated rate of increase, references the second relationship data showing the relationship between Warburg impedance and SOH stored in storage 10 (S23) to estimate the SOH (S24).

Thus, in the present embodiment, a low current interval during which current flowing through cells C0 through C7 is less than or equal to a threshold value is identified, and by using a voltage of cell Cn measured during the low current interval as a provisional OCV, the OCV, SOC, and SOH of cell stack 1 are estimated. Therefore, even in a case where cell stack 1 is used in a state of being constantly charged and discharged, the OCV, SOC, and SOH of cell stack 1 can be accurately estimated.

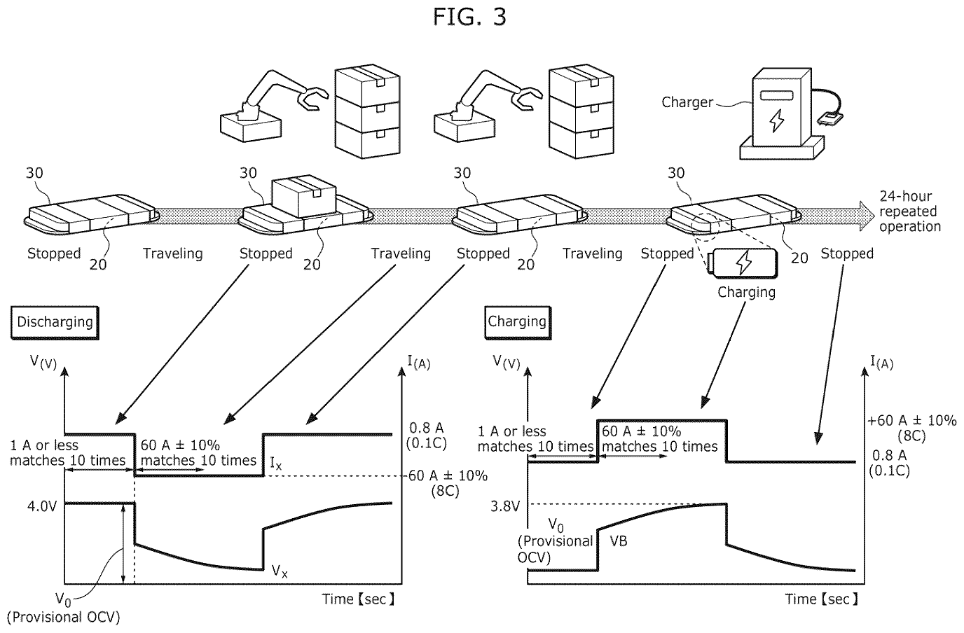

FIG. 3 is for explaining the relationship between operations performed by AGV 30 equipped with battery monitoring device 20 according to an embodiment of the present disclosure and operations performed by battery monitoring device 20.

While cell stack 1 equipped in AGV 30 is being charged and discharged by an application of AGV 30 that uses cell stack 1, the voltage, current, and temperature of cell stack 1 are periodically measured by battery monitoring device 20. When the application (i.e., AGV 30) is stopped or in standby, battery monitoring device 20 detects a preset low current interval, and calculates a provisional OCV of cell stack 1 in that low current interval. However, when the application causes AGV 30 to travel and discharging occurs, or when charging is performed, a transient response voltage is confirmed, so battery monitoring device 20 transitions to a flow of operations for calculating the impedances of cells C0 through C7, and estimates the SOH of cells C0 through C7 from the rate of increase of Warburg impedance Zw. After calculating Warburg impedance Zw, battery monitoring device 20 updates the initial OCV stored in storage 10 with the first OCV derived from the provisional OCV, and uses the updated OCV to calculate and monitor the SOC and the SOH of cell stack 1. The calculated OCV, SOC, and SOH are stored in storage 10 and external storage device 12.

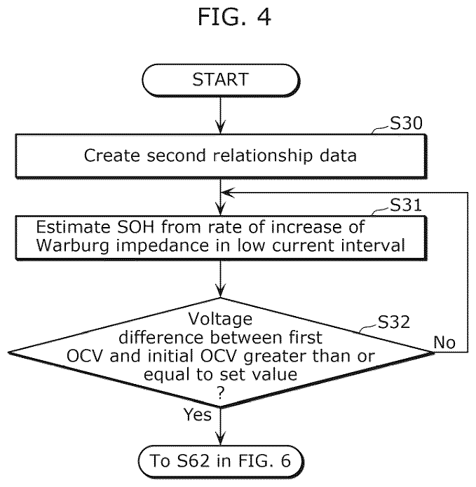

Next, detailed operations performed by battery monitoring device 20 according to the present embodiment will be described using the flowcharts of FIG. 4 through FIG. 7.

FIG. 4 is a flowchart illustrating detailed operations performed by battery monitoring device 20 according to an embodiment of the present disclosure.

First, as data preparation to be performed in advance, second relationship data indicating a relationship between Warburg impedance and SOH is created and stored in storage 10 of battery monitoring device 20 (S30).

Next, after the application of the AGV equipped with battery monitoring device 20 has started operating, battery monitoring device 20 identifies a low current interval, and calculates a provisional OCV and Warburg impedance for cells C0 through C7 in the identified low current interval, and estimates the present SOH from the rate of increase of the Warburg impedance (S31).

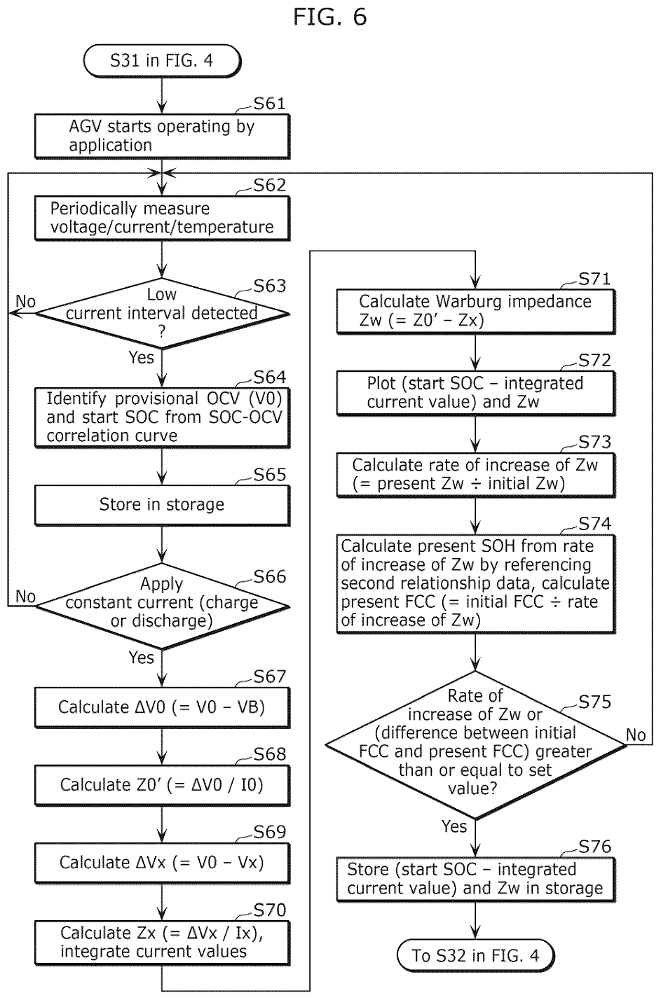

Next, battery monitoring device 20 determines whether a voltage difference between a first OCV, which is obtained by correcting the provisional OCV in consideration of the total impedance (i.e., internal impedance) of cell Cn, and the initial OCV stored in storage 10 is greater than or equal to a set value (S32), and when the voltage difference is greater than or equal to the set value, updates the initial OCV stored in storage 10 by overwriting it with the first OCV (Yes in S32), and proceeds to step S62 in FIG. 6 showing step S31 in detail, whereas when the voltage difference is not greater than or equal to the set value (No in S32), repeats steps S31 through S32.

This enables battery monitoring device 20 to estimate the OCV, SOC, and SOH of cell stack 1 by utilizing the low current interval, even in case where cell stack 1 is used in a state of being constantly charged and discharged.

In FIG. 4 through FIG. 7, the processing for storing in storage 10 may be performed by storing in external storage device 12 via communication unit 11, instead of or in addition to storing in storage 10.

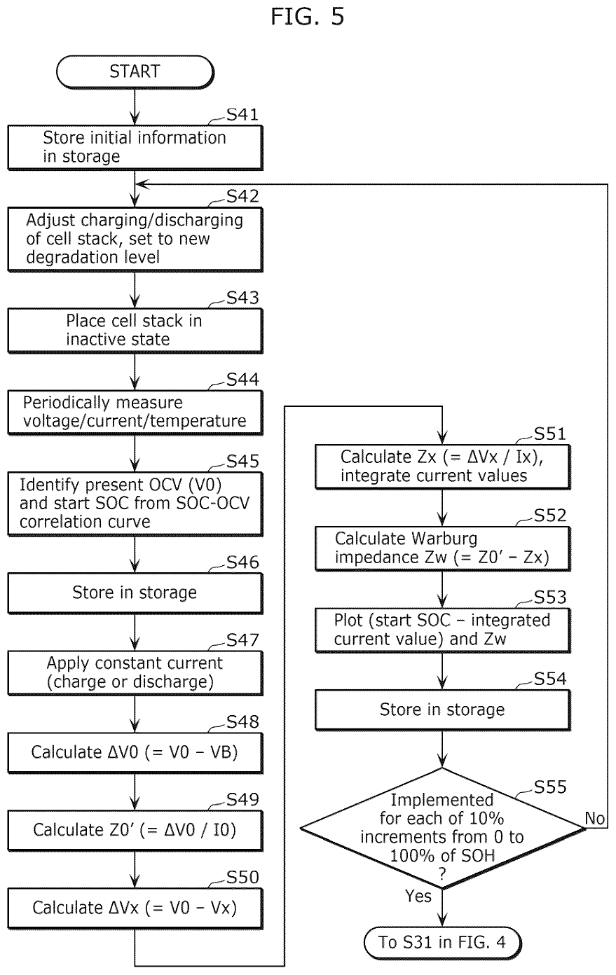

FIG. 5 is a flowchart illustrating the procedures of step S30 (preparation of second relationship data) in FIG. 4 in greater detail. Here, the processing of this flowchart is described as being executed mainly by calculation unit 14 of battery monitoring device 20, but the processing is not limited to this, and may be executed mainly by a computer or the like communicably connected to battery monitoring device 20.

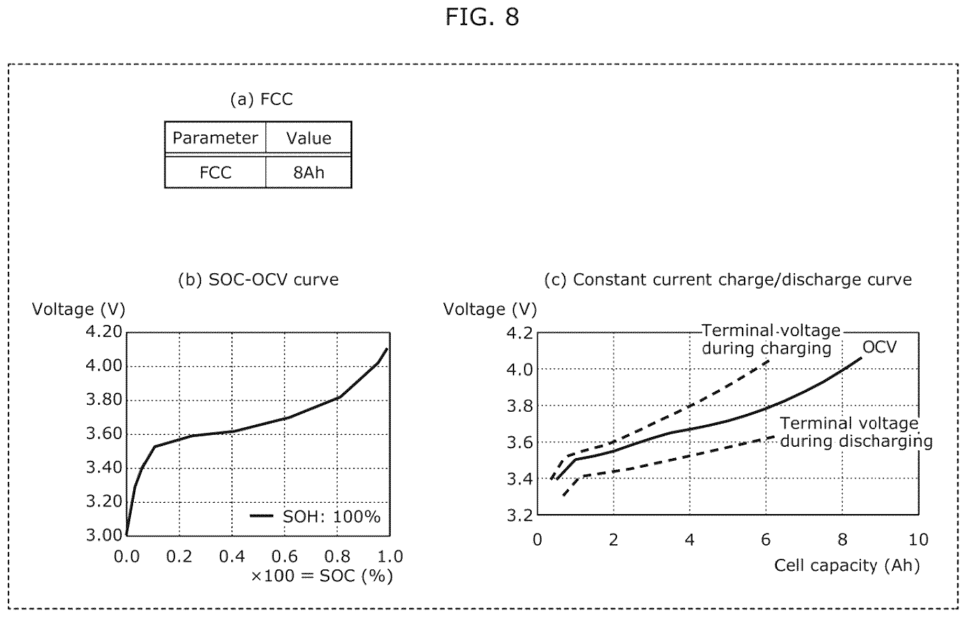

First, initial information of cell stack 1 that is known in advance is stored in storage 10 (S41). Here, the initial information of cell stack 1 is information on the initial state of cells C0 through C7 of cell stack 1, and specifically includes the SOC-OCV correlation curve (first relationship data) when the SOH is 100%, the constant current charge/discharge curve, and the initial full charge capacity (FCC) (refer to FIG. 8 (to be described later)). Since the impedance of cell Cn changes exponentially with changes in the ambient temperature of cell stack 1, a correlation equation between the impedance of cell Cn and temperature may also be stored for the purpose of temperature correction of the impedance.

Next, by adjusting the charging and discharging of cell stack 1, the degradation level of cell stack 1 is set to a new state (for example, one of states obtained by dividing the SOH of cell Cn from 0 to 100% in 10% increments) (S42).

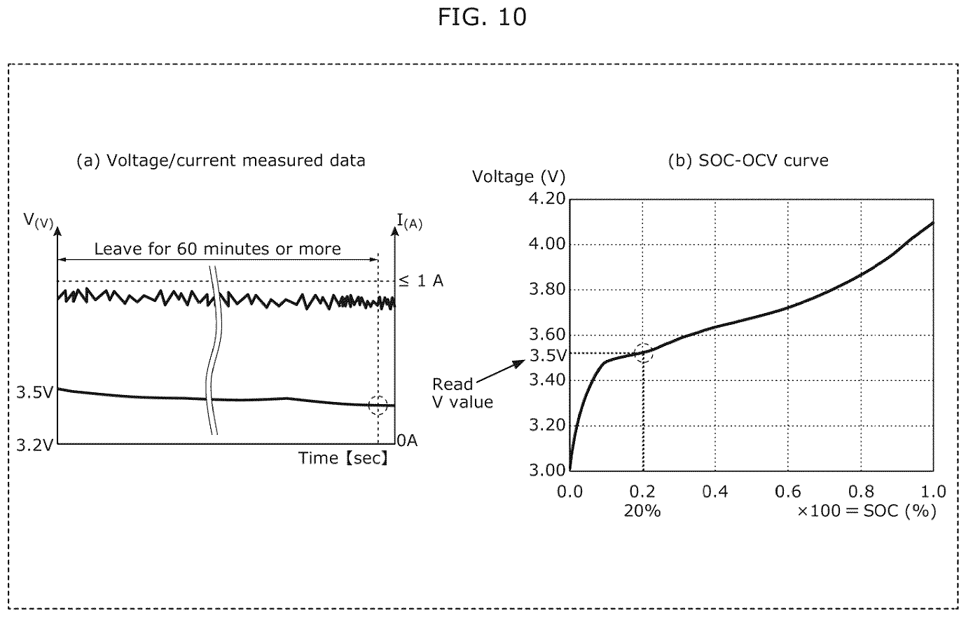

Next, cell stack 1 is placed in an inactive state (for example, left for 60 minutes or more after current is stopped) (S43), and measurement unit 13 periodically (for example, at intervals of 1 ms to several ms) measures the voltage, current, and temperature of cell stack 1 (S44). Based on the SOC-OCV correlation curve stored in storage 10 and the voltage data measured in step S44, the present OCV (i.e., voltage V0) and the start SOC for cell Cn are identified (S45; refer to FIG. 10 (to be described later)), and the identified present OCV and start SOC are stored in storage 10 (S46).

Next, a constant current is applied to cell stack 1 (i.e., charging or discharging is performed) using an external charger or load (S47). For example, current measurement unit 4 detects that an application of a current of 60 A±10% matches 10 times.

Voltage value difference ΔV0 is calculated according to the following equation based on the present OCV (voltage V0) obtained in step S46 and voltage VB at the start of the charge/discharge interval of time T (S48).

$$Δ V 0 = V 0 - VB$$

Based on the calculated voltage value difference ΔV0 and current 10 at the start of the charge/discharge interval, impedance Z0′ is calculated according to the following equation (S49).

$$Z {0}^{′} = Δ V 0 / I 0$$

Voltage value difference ΔVx is calculated according to the following equation based on the present OCV (voltage V0) obtained in step S45 and voltage Vx at the end of the charge/discharge interval after time T has elapsed (S50).

$$Δ Vx = V 0 - Vx$$

Based on calculated voltage value difference ΔVx and current Ix at the end of the charge/discharge interval, impedance Zx is calculated according to the following equation, and the integrated current value is calculated by integrating the current value over time T (charge/discharge interval) (S51).

$$Zx = Δ Vx / Ix$$

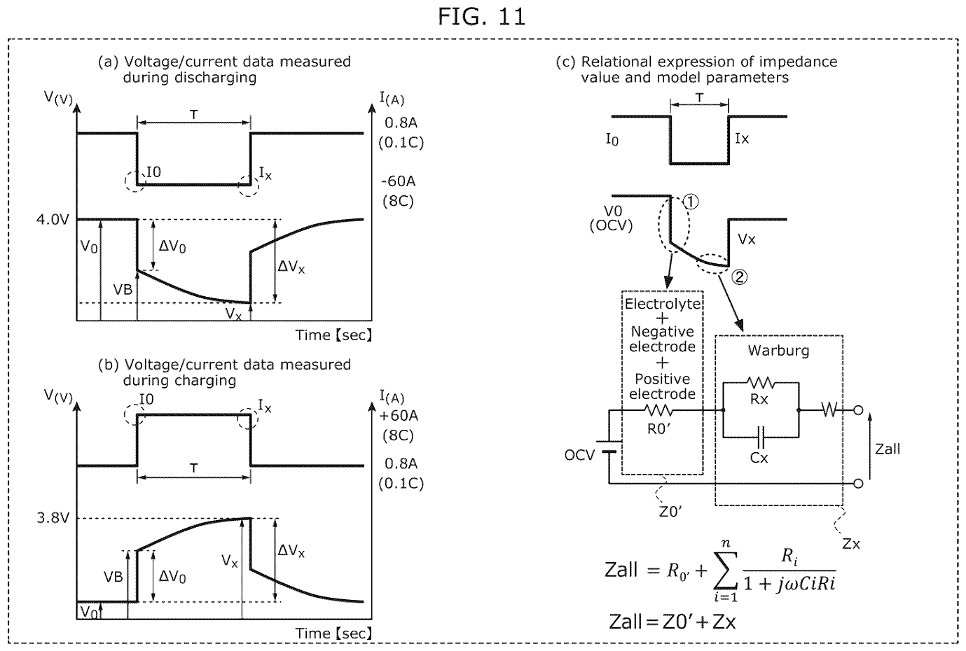

Warburg impedance Zw of cell Cn is calculated according to the following equation by calculating the difference in values between impedance Z0′ calculated in step S49 and impedance Zx calculated in step S51 (S52; refer to FIG. 11 (to be described later)).

$$Zw = Z {0}^{′} - Zx$$

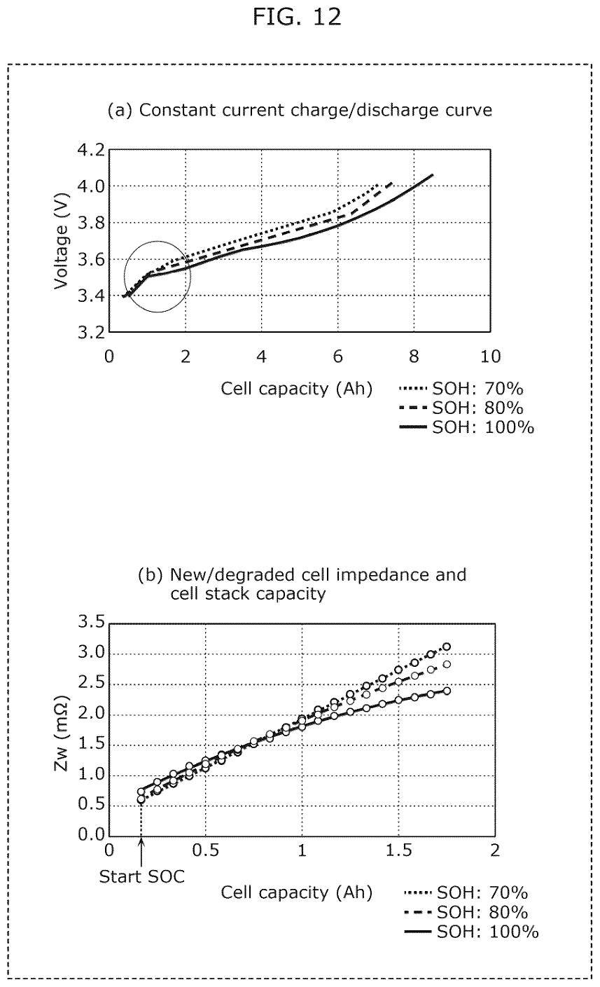

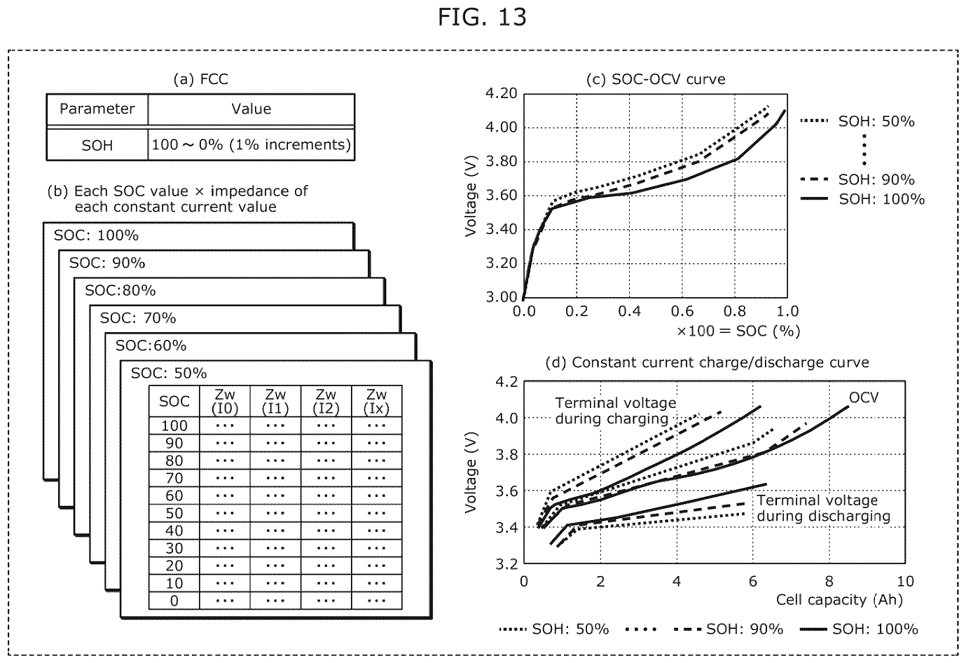

A point defined by the relationship between the cell capacity (or present SOC) obtained by subtracting the integrated current value calculated in step S51 from the start SOC, and Warburg impedance Zw obtained in step S52, is plotted (S53; refer to (b) in FIG. 12 (to be described later)), and the result is stored in storage 10 as initial second relationship data indicating the relationship between Warburg impedance, SOC, and SOH (S54; refer to FIG. 13 (to be described later)).

Next, it is determined whether processing has been completed for all of the different degradation levels (for example, levels obtained by dividing the SOH of cell Cn from 0 to 100% in 10% increments) of cell stack 1 (S55). If it is determined that processing has not been completed (No in S55), the processing of steps S42 to S55 is repeated. If it is determined that processing has been completed (Yes in S55), the processing shown in FIG. 5 ends, and proceeds to the next step (step S31 in FIG. 4).

In this way, the initial second relationship data indicating the relationship between Warburg impedance, SOC, and SOH is created and stored in storage 10.

FIG. 6 is a flowchart illustrating the procedures of step S31 (present SOH estimation) in FIG. 4 in greater detail. Here, the processing executed mainly by calculation unit 14 of battery monitoring device 20 is shown. The processing for cell Cn is similarly performed for each of cells C0 through C7.

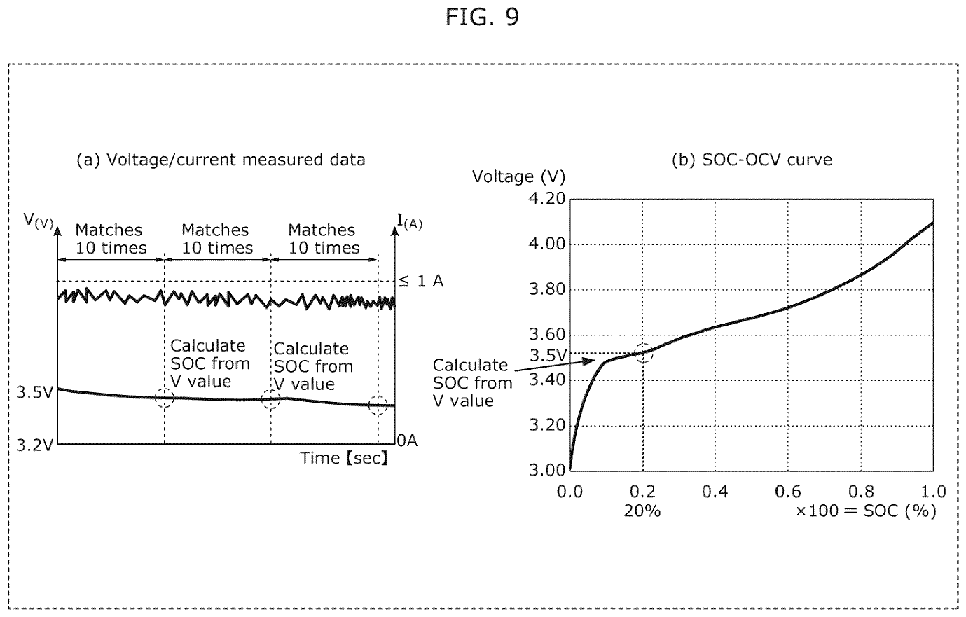

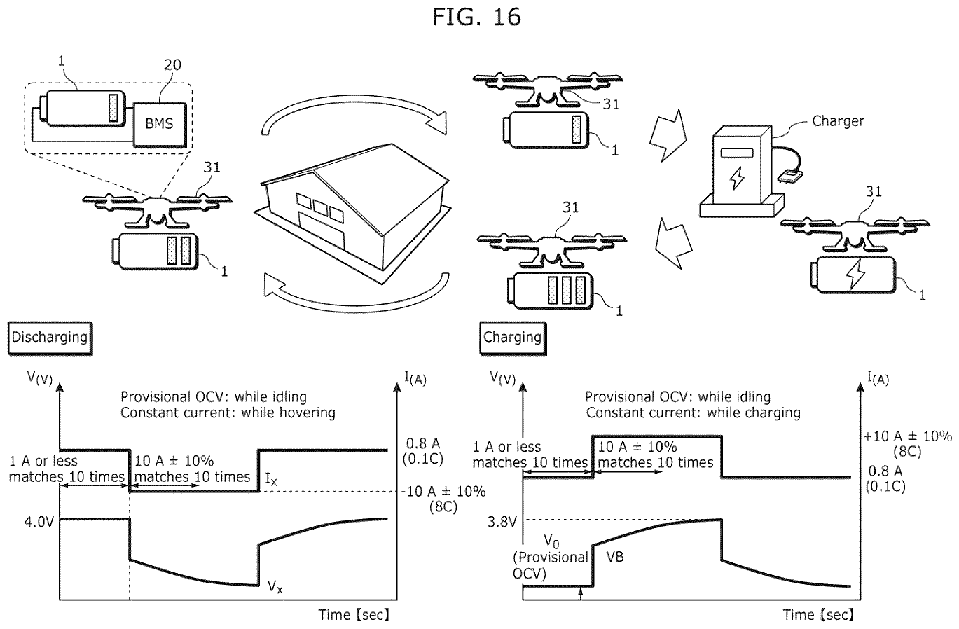

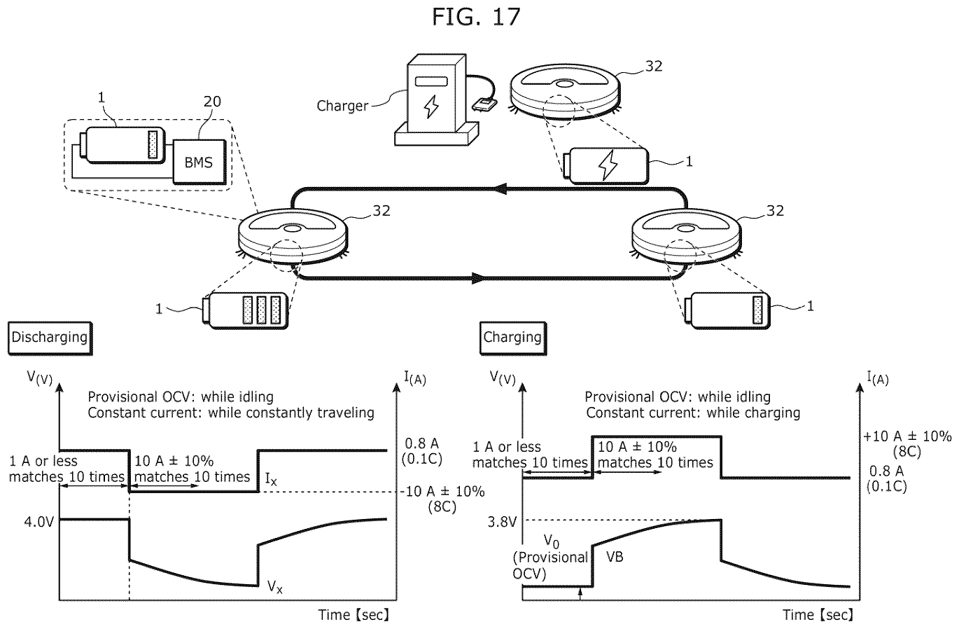

When AGV 30 starts operating due to the application (S61; refer to FIG. 3, FIG. 16 and FIG. 17 (to be described later)), by measurement unit 13 periodically (for example, at intervals of 1 ms to several ms) measuring the voltage, current, and temperature of cell stack 1 (S62), it is determined whether a low current interval of a certain time or longer could be detected (S63; refer to FIG. 9 and FIG. 10 (to be described later)). For example, it is determined whether a current of 1 A or less could be detected 10 times.

As a result, when a low current interval of a certain time or longer could be detected (Yes in S63), for cell Cn, the measured voltage obtained in step S62 is used as the provisional OCV (voltage V0), and the SOC is calculated (S64) by referencing the SOC-OCV correlation curve stored in storage 10, and stored in storage 10 as the start SOC (S65).

Next, it is determined whether application of a constant current (i.e., charging or discharging) using an external charger or load has been detected (S66). For example, it is determined whether an application of a current of 60 A±10% matches 10 times.

As a result, when it is determined that application of a constant current has been detected (Yes in S66), voltage value difference ΔV0 is calculated according to the following equation based on the provisional OCV (voltage V0) obtained in step S64 and voltage VB at the start of the charge/discharge interval of time T (S67).

$$Δ V 0 = V 0 - VB$$

Based on the calculated voltage value difference ΔV0 and current 10 at the start of the charge/discharge interval, impedance Z0′ is calculated according to the following equation (S68).

$$Z {0}^{′} = Δ V 0 / I 0$$

Voltage value difference ΔVx is calculated according to the following equation based on the provisional OCV (voltage V0) obtained in step S64 and voltage Vx at the end of the charge/discharge interval after time T has elapsed (S69).

$$Δ Vx = V 0 - Vx$$

Based on calculated voltage value difference ΔVx and current Ix at the end of the charge/discharge interval, impedance Zx is calculated according to the following equation, and the integrated current value is calculated by integrating the current value over time T (charge/discharge interval) (S70).

$$Zx = Δ Vx / Ix$$

Warburg impedance Zw of cell Cn is calculated according to the following equation by calculating the difference in values between impedance Z0′ calculated in step S68 and impedance Zx calculated in step S70 (S71; refer to FIG. 11 (to be described later)).

$$Zw = Z {0}^{′} - Zx$$

A point defined by the relationship between the cell capacity (or present SOC) obtained by subtracting the integrated current value calculated in step S70 from the start SOC, and Warburg impedance Zw obtained in step S71, is plotted (i.e., stored in storage 10) (S72; refer to (b) in FIG. 12 (to be described later)).

Next, the rate of increase of Zw is calculated according to the following equation based on the Warburg impedance obtained in step S71 (i.e., the present Zw) and the Warburg impedance obtained in step S52 of FIG. 5 (i.e., the initial Zw) (S73).

rate of increase of Zw=present Zw÷initial Zw

The present SOH is estimated by referencing the second relationship data stored in storage 10 (refer to FIG. 13 (to be described later)) using the calculated rate of increase of Zw and the present SOC (S74). The present FCC is calculated according to the following equation based on the rate of increase of Zw and the initial FCC stored in storage 10.

present FCC=initial FCC÷rate of increase of Zw

Next, it is determined whether the rate of increase of Zw is greater than or equal to a set value, or whether the difference between the present FCC calculated by the above equation and the initial FCC is greater than or equal to a set value (S75). If it is determined that either value is greater than or equal to the set value (Yes in S75), it is determined that degradation of cell Cn has progressed, and the second relationship data stored in storage 10 is updated with the present FCC, the cell capacity (or present SOC) obtained in step S72, and Warburg impedance Zw (S76; refer to FIG. 12 and FIG. 13 (to be described later)). This enables the second relationship data indicating the relationship between Warburg impedance, SOC, and SOH to be updated when it is determined that degradation of cell Cn has progressed. Note that when it is determined that neither value is greater than or equal to the set value (No in S75), it is determined that the degradation of cell Cn has not progressed, and the processing after step S62 is repeated.

The processing of step S31 (present SOH estimation) in FIG. 4, illustrated in FIG. 6 as described above, has the following features.

Generally, OCV refers to the terminal voltage of cell Cn in an open circuit state, that is, the terminal voltage in a no-load state, but in the present embodiment, it is determined that cell stack 1 is in a low current interval, and the voltage of cell Cn measured in that low current interval is determined to be an approximate OCV (i.e., a provisional OCV), and the state of cell stack 1 is monitored. Measurement unit 13 periodically measures the voltage, current, and temperature of cell stack 1, and in state where cell stack 1 is constantly being charged and discharged (i.e., assuming a state where the application is operating and being used 24 hours day), measurement unit 13 investigates a preset low current interval. Calculation unit 14 calculates the provisional OCV in the investigated low current interval. In a state of constantly being charged and discharged, the state of correlation between OCV and SOC can be managed using the provisional OCV.

Measurement unit 13 determines a state where the current has switched from the low current interval to a transient current (i.e., pulse current), and measures the voltage, current, and time during which the current is flowing. Calculation unit 14 calculates the impedance from the voltage, current, and time during which the current is flowing measured in the transient response, and calculates Warburg impedance Zw from the voltage, current, and time during which the current is flowing in the transient response illustrated in FIG. 11 and the equivalent circuit model of cell Cn. Based on the initial Warburg impedance stored in storage 10 (initial Zw) and the Warburg impedance when the application is operating (present Zw), the rate of increase of the Warburg impedance (=present Zw=initial Zw) is calculated, and the SOH when the application is operating is calculated from the SOH conversion table (second relationship data) stored in storage 10.

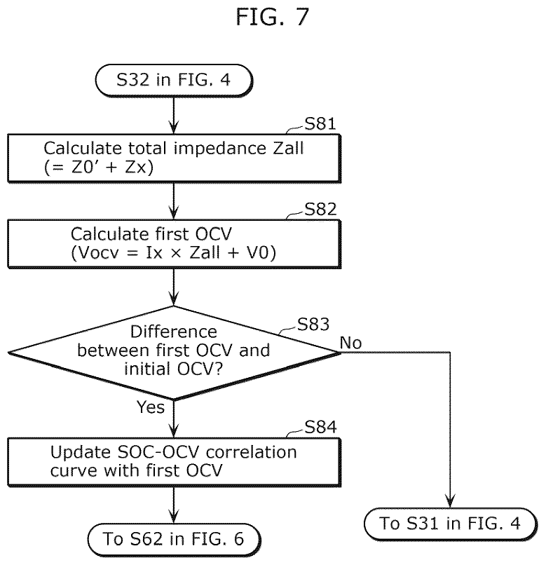

FIG. 7 is a flowchart illustrating the procedures of step S32 (determination using the voltage difference between the first OCV and the initial OCV) in FIG. 4 in greater detail. Here, the processing executed mainly by calculation unit 14 of battery monitoring device 20 is shown. The processing for cell Cn is similarly performed for each of cells C0 through C7.

The total impedance (i.e., internal impedance) Zall of cell Cn is calculated according to the following equation based on impedance Z0′ calculated in step S68 of FIG. 6 and impedance Zx calculated in step S70 of FIG. 6 (S81).

$$Zall = Z {0}^{′} + Zx$$

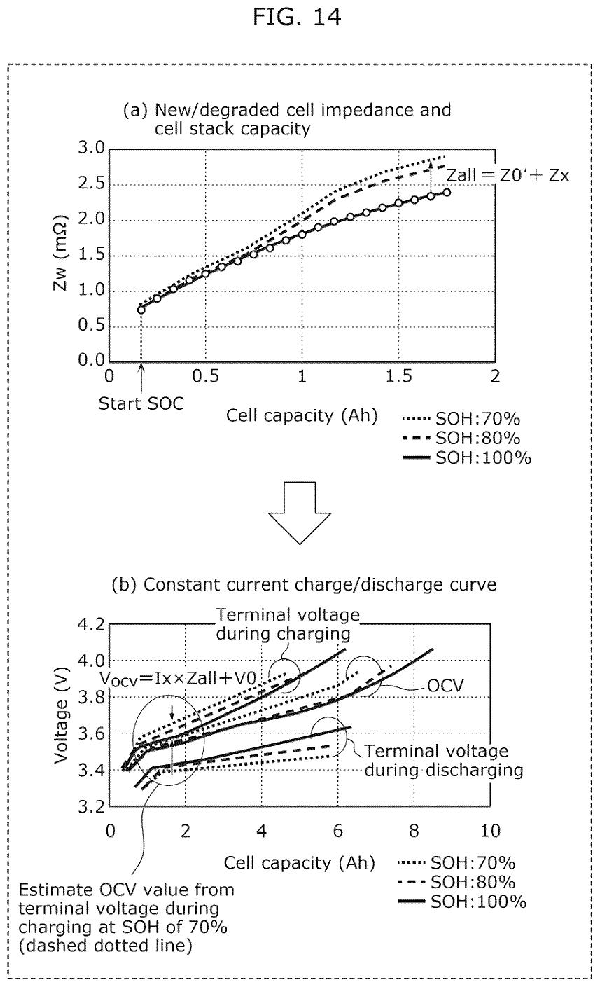

The first OCV (i.e., voltage Vocv), which is the present OCV, is calculated according to the following equation based on the calculated total impedance Zall, current Ix at the end of the charge/discharge interval used in step S70 of FIG. 6, and the provisional OCV (i.e., voltage V0) obtained in step S64 of FIG. 6 (S82; refer to FIG. 14 (to be described later)).

$$Vocv = Ix \times Zall + V 0$$

This is to calculate the present first OCV (voltage Vocv) by correcting the voltage drop at total impedance Zall due to the charge/discharge current with respect to the provisional OCV (voltage V0).

Calculation unit 14 references the first relationship data stored in storage 10 to identify, as an initial OCV, an OCV corresponding to an SOC obtained by subtracting the integrated value obtained by current integrate unit 8b from the start SOC corresponding to the provisional OCV, determines whether the difference between the identified initial OCV and the first OCV is greater than or equal to a threshold value (for example, 10 mV) (S83), and when there is a difference (Yes in S83), updates the initial OCV in the first relationship data using the first OCV (S84), and returns to step S62 in FIG. 6, whereas when there is no difference (No in S83), returns to step S31 in FIG. 4.

In this way, during operation of the application of AGV 30, the present first OCV (voltage Vocv) is estimated, and when there is a large difference between the OCV (i.e., initial OCV) on the SOC-OCV correlation curve (first relationship data) stored in storage 10, the SOC-OCV correlation curve (first relationship data) stored in storage 10 is updated with the present first OCV (voltage Vocv). Stated differently, at the start of the application, the SOC is monitored using the initial OCV stored in storage 10, but after the OCV is updated by the process illustrated in FIG. 7, the SOC is monitored more accurately using the updated OCV.

Next, FIG. 8 through FIG. 18 referenced in the flowcharts of FIG. 4 through FIG. 7 will be described.

FIG. 8 illustrates an example of initial information of cell stack 1. More specifically, the initial information of cell stack 1 is initial information for secondary cells of the same type as cells C0 through C7 of cell stack 1, where (a) in FIG. 8 illustrates an example of initial FCC data of the secondary cells, (b) in FIG. 8 illustrates an example of an SOC-OCV correlation curve (first relationship data) of the secondary cells, and (c) in FIG. 8 illustrates an example of a constant current charge/discharge curve, that is, a cell capacity-voltage (terminal voltage during charging, terminal voltage during discharging, and OCV) correlation curve. These are stored in advance in storage 10 of battery monitoring device 20 (and/or external storage device 12) (S41 in FIG. 5).

In the example data illustrated in (a) in FIG. 8, 8 Ah is registered as the initial full charge capacity (FCC) of the secondary cell.

The SOC-OCV correlation curve illustrated in (b) in FIG. 8 is a curve with SOC on the horizontal axis and the terminal voltage of the secondary cell in an open circuit state, that is, the OCV, which is the voltage of the secondary cell when no current is flowing, on the vertical axis. The SOC of the secondary cell is defined based on the OCV of the secondary cell. For example, the lower limit voltage of the OCV is defined as the state where the SOC is 0%, and the upper limit voltage of the OCV is defined as the state where the SOC is 100%. The discharge capacity from the state where the SOC is 100% to the state where the SOC is 0%, or the charge capacity from the state where the SOC is 0% to the state where the SOC is 100%, becomes the cell capacity. The SOC is defined as the ratio of the remaining charge capacity to the total cell capacity, where 0% SOC represents a completely discharged cell. Therefore, the SOC of the secondary cell can be calculated based on the OCV and the charge-discharge capacity of the secondary cell. If the SOC-OCV correlation curve is available, the approximate SOC can be determined by measuring the voltage of the secondary cell.

The constant current charge/discharge curve illustrated in (c) in FIG. 8 indicates the current pattern used in the application, and is a correlation curve between the cell capacity (horizontal axis) of the secondary cell and the voltage (vertical axis) of the secondary cell. Generally, information accompanying a constant current charge/discharge curve includes, for example, conditions related to the operating voltage range of the secondary cell during charging and discharging, conditions of the current (C-rate of the secondary cell) flowing through the secondary cell during charging and discharging, conditions related to the temperature of the secondary cell during charging and discharging, and conditions for ending charging and discharging.

FIG. 9 is for explaining an example of determination of a low current interval by battery monitoring device 20 (an example of using the number of investigations). More specifically, (a) in FIG. 9 illustrates an example of measured data of the voltage and current of cell Cn, and (b) in FIG. 9 illustrates a process of determining the SOC using an SOC-OCV correlation curve.

When calculating the OCV, SOC, and SOH of cell Cn, calculation unit 14 of battery monitoring device 20 first determines whether the present time is in a low current interval by the determination illustrated in FIG. 9 (S10 in FIG. 2, S63 in FIG. 6).

More specifically, as illustrated in (a) in FIG. 9, calculation unit 14 periodically measures the voltage and current of cell stack 1, and when a state where the current flowing in cell stack 1 is a low current (i.e., 0.2 C or less as the C-rate (i.e., a current value of 1 A when the initial cell capacity is 8 Ah) in (a) in FIG. 9) is consecutively detected a predetermined number of times (10 times in (a) in FIG. 9), determines that the present time is in a low current interval. When it is determined that the present time is in a low current interval, as illustrated in (b) in FIG. 9, calculation unit 14 uses the voltage V of cell Cn (i.e., the provisional OCV) immediately after making that determination as the OCV, and calculates the SOC (or start SOC) by checking it against the SOC-OCV correlation curve stored in storage 10.

FIG. 10 is for explaining an example of determination of a low current interval by battery monitoring device 20 (an example of using the investigation time). More specifically, (a) in FIG. 10 illustrates an example of measured data of the voltage and current of cell Cn, and (b) in FIG. 10 illustrates a process of determining the SOC using an SOC-OCV correlation curve.

When calculating the OCV, SOC, and SOH of cell Cn, calculation unit 14 of battery monitoring device 20 first determines whether the present time is in a low current interval by the determination illustrated in FIG. 10 (S10 in FIG. 2, S63 in FIG. 6).

More specifically, as illustrated in (a) in FIG. 10, calculation unit 14 uses an internal timer to repeatedly measure the voltage and current of cell stack 1, and when a state where the current flowing in cell stack 1 is a low current (i.e., 0.2 C or less as the current rate (i.e., a current value of 1 A when the initial cell capacity is 8 Ah) in (a) in FIG. 10) is consecutively detected for a predetermined time (60 minutes in (a) in FIG. 10), determines that the present time is in a low current interval. When it is determined that the present time is in a low current interval, as illustrated in (b) in FIG. 10, calculation unit 14 uses the voltage V of cell Cn (i.e., the provisional OCV) immediately after making that determination as the OCV, and calculates the SOC (or start SOC) by checking it against the SOC-OCV correlation curve stored in storage 10.

FIG. 11 is for explaining the method of calculating Warburg impedance by battery monitoring device 20. More specifically, (a) in FIG. 11 illustrates waveforms of the voltage and current of cell Cn during discharging of cell stack 1, (b) in FIG. 11 illustrates waveforms of the voltage and current of cell Cn during charging of cell stack 1, and (c) in FIG. 11 illustrates the relationship between the current and voltage waveforms of cell Cn during discharging and the model parameters in the equivalent circuit of cell Cn (i.e., a lithium-ion secondary cell).

As illustrated in the equivalent circuit in (c) in FIG. 11, the internal impedance of cell Cn (i.e., a lithium-ion secondary cell) is expressed as a series connection of impedance Z0′ of the electrolyte, negative electrode, and positive electrode, and impedance Zx that includes Warburg impedance Zw and other impedances.

From this, impedance Z0′ (=ΔV0/I0) corresponding to resistance R0′ in the equivalent circuit shown in (c) in FIG. 11 is calculated for cell Cn by dividing voltage value difference ΔV0 (=V0-VB) between the present OCV (voltage V0) obtained in the inactive state or low current interval and voltage VB at the start of the charge/discharge interval by current 10 at the start of the charge/discharge interval (S21 in FIG. 2, S48 in FIG. 5, S67 in FIG. 6). Instead of dividing by current 10, the division may be performed using current difference ΔI (=10-IL) between current 10 and current IL in the low current interval.

On the other hand, impedance Zx (=ΔVx/Ix) in the equivalent circuit shown in (c) in FIG. 11 is calculated by dividing voltage value difference ΔVx (=V0-Vx) between the present OCV (voltage V0) and voltage Vx at the end of the charge/discharge interval by current Ix at the end of the charge/discharge interval (S21 in FIG. 2, S51 in FIG. 5, S70 in FIG. 6). Instead of dividing by current Ix, the division may be performed using current difference AI (=Ix-IL) between current Ix and current IL in the low current interval.

Therefore, Warburg impedance Zw (=Z0′-Zx) of cell Cn is obtained by calculating the difference between the former impedance Z0′ and the latter impedance Zx (S21 in FIG. 2, S52 in FIG. 5, S71 in FIG. 6). The total impedance (i.e., the internal impedance) Zall of cell Cn is expressed as Zall=Z0′+Zx.

FIG. 12 illustrates the SOH dependency of a secondary cell. More specifically, (a) in FIG. 12 illustrates the SOH dependency in the constant current charge/discharge curve, that is, the cell capacity (horizontal axis)-voltage (OCV, vertical axis) correlation curve, and (b) in FIG. 12 illustrates the SOH dependency in the cell capacity (horizontal axis)-Warburg impedance Zw (vertical axis) correlation curve. These curves, when obtained by measurement, are stored in storage 10.

One factor that causes SOH to decrease is an increase in impedance. As illustrated in the SOH dependency of the cell capacity-voltage correlation curve in (a) in FIG. 12, the lower the SOH, the greater the rate of increase of voltage with respect to the cell capacity. As illustrated in the SOH dependency of cell capacity-Warburg impedance Zw correlation curve in (b) in FIG. 12, the lower the SOH, the greater the rate of increase of Warburg impedance Zw with respect to the cell capacity.

From these, it is clear that the SOH of a secondary cell can be estimated from the cell capacity (or the present SOC) and the rate of increase of Warburg impedance Zw.

FIG. 13 is for explaining the impedance-SOH correlation table (i.e., the second relationship data) that indicates the relationship between impedance and SOH and is created using the secondary cell characteristics illustrated in FIG. 12. More specifically, (a) in FIG. 13 illustrates an example of the current SOH data of cell Cn, (b) in FIG. 13 illustrates a table (i.e., second relationship data) showing the relationship between SOC and Warburg impedance Zw corresponding to each constant current value, for each SOH of cell Cn, (c) in FIG. 13 illustrates the SOH dependency of the SOC-OCV correlation curve, and (d) in FIG. 13 illustrates the SOH dependency and charge/discharge dependency of the constant current charge/discharge curve, that is, the cell capacity-voltage (terminal voltage during charging, terminal voltage during discharging, OCV) correlation curve. This data is stored in storage 10.

Calculation unit 14 estimates the SOH of cell Cn from Warburg impedance Zw (strictly speaking, the rate of increase of Warburg impedance Zw) and the present SOC, by referencing the second relationship data illustrated in (b) in FIG. 13 (S24 in FIG. 2, S31 in FIG. 4, S74 in FIG. 6). Here, in addition to or instead of the second relationship data illustrated in (b) in FIG. 13, the SOH of cell Cn may be estimated from the terminal voltage, the present SOC, or the cell capacity (or the present SOC) of cell Cn by referencing the SOH dependency of the SOC-OCV correlation curve illustrated in (c) in FIG. 13 or the SOH dependency of the constant current charge/discharge curve illustrated in (d) in FIG. 13. The second relationship data illustrated in (b) in FIG. 13 may be expressed as a table using the SOH, the SOC, and the rate of increase of Warburg impedance Zw.

FIG. 14 is for explaining the basis for calculating the present OCV (i.e., the first OCV) from the provisional OCV using total impedance (i.e., the internal impedance) Zall of a secondary cell. More specifically, (a) in FIG. 14 illustrates the SOH dependency of the correlation curve between the cell capacity (horizontal axis) and total impedance Zall (vertical axis) of a secondary cell, and (b) in FIG. 14 illustrates the SOH dependency of the constant current charge/discharge curve for the terminal voltage during charging/discharging and the OCV.

As illustrated in (a) in FIG. 14, as degradation of the secondary cell progresses (i.e., as the SOH decreases), the higher the cell capacity is, the greater total impedance Zall becomes.

From this, as illustrated in (b) in FIG. 14, when a current due to charging or discharging flows through the secondary cell, an extra voltage (i.e., a voltage drop) caused by total impedance Zall occurs, and that voltage is added during charging and subtracted during discharging, and is measured as the terminal voltage. In calculation unit 14, the extra voltage (i.e., Ix×Zall) is calculated from the calculated total impedance Zall, and the OCV of the secondary cell after degradation, that is, the first OCV (=Ix×Zall+V0), is calculated by adding it during charging and subtracting it during discharging to and from the initial OCV (i.e., voltage V0) stored in storage 10. The initial OCV stored in storage 10 is updated with this post-degradation first OCV, and the state of the secondary cell is monitored using the updated OCV. (b) in FIG. 14 illustrates an example of estimating the OCV from the terminal voltage during charging at, for example, a SOH of 70% (dotted line).

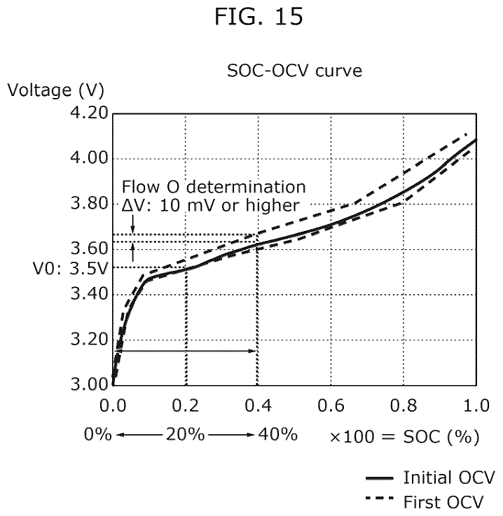

FIG. 15 is for explaining a method of updating the SOC-OCV correlation curve (i.e., the first relationship data) stored in storage 10.

Calculation unit 14 references the first relationship data stored in storage 10 to identify, as an initial OCV, an OCV corresponding to an SOC obtained by subtracting the integrated value obtained by current integrate unit 8b from the start SOC corresponding to the provisional OCV, and when the difference between the identified initial OCV and the first OCV is greater than or equal to a threshold value (for example, 10 mV), updates the initial OCV in the first relationship data using the first OCV. Calculation unit 14 then monitors the SOC of cell Cn using the updated OCV stored in storage 10. Stated differently, at the start of the application, the SOC is monitored using the initial OCV stored in storage 10, but thereafter, the OCV stored in storage 10 is repeatedly updated. Updating the OCV in this manner inhibits unintended stopping of the application due to erroneous recognition of the SOC.

FIG. 16 is for explaining an operation example of drone 31 equipped with cell stack 1 and battery monitoring device 20. In this example, battery monitoring device 20 is equipped in drone 31 and periodically measures the voltage, current, and temperature while cell stack 1 is being charged and discharged by an application that uses cell stack 1. When a low current interval is detected while the application is in standby, the battery monitoring device measures the provisional OCV at that point. When a constant current is applied (i.e., when charging or discharging is performed) during operation of the application, the battery monitoring device transitions to a flow of operations for calculating the impedance of cell stack 1, and performs SOH degradation estimation.

FIG. 17 is for explaining an operation example of cleaning robot 32 equipped with cell stack 1 and battery monitoring device 20. In this example as well, similar to the operation example of drone 31 illustrated in FIG. 16, battery monitoring device 20 is equipped in cleaning robot 32 and periodically measures the voltage, current, and temperature while cell stack 1 is being charged and discharged by an application that uses cell stack 1. When a low current interval is detected while the application is in standby, the battery monitoring device measures the provisional OCV at that point. When a constant current is applied (i.e., when charging or discharging is performed) during operation of the application, the battery monitoring device transitions to a flow of operations for calculating the impedance of cell stack 1, and performs SOH degradation estimation.

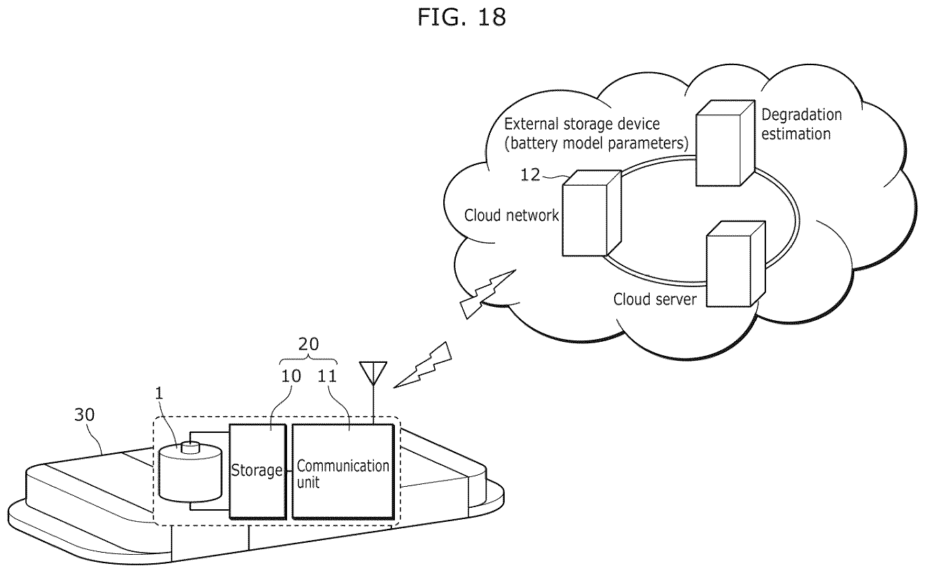

FIG. 18 illustrates an example of communication between battery monitoring device 20 and external storage device 12. Battery monitoring device 20 is equipped in AGV 30 and communicates with external storage device 12 constituting a cloud via communication unit 11 regarding various data stored in storage 10. For example, the data in storage 10 and external storage device 12 can be synchronized by outputting the SOC and the SOH stored in storage 10 to external storage device 12. Additionally, high-precision battery state estimation can be maintained by downloading data corresponding to the latest type of secondary cell from external storage device 12 and updating the data in storage 10 (for example, the first relationship data, second relationship data, initial information, and battery model parameters). For example, external storage device 12 is connected to or equipped in a computer (server) connected via a communication network such as the Internet, or a server in a cloud environment. In such cases, battery monitoring device 20 may download programs necessary for estimating the battery state via a communication network.

As described above, battery monitoring device 20 according to the present embodiment monitors a state of cell stack 1 including secondary cells C0 to C7 connected in series or parallel, and includes: measurement unit 13 that measures a state of secondary cells C0 to C7; and calculation unit 14 that calculates and estimates the SOC and the SOH of secondary cells C0 to C7 based on the state of secondary cells C0 to C7 measured. Measurement unit 13 includes: voltage measurement unit 3 that measures a voltage of secondary cells C0 to C7; and current measurement unit 4 that measures current flowing through secondary cells C0 to C7. Calculation unit 14 includes: storage 10 that holds at least first relationship data indicating a relationship between SOC and OCV of cell stack 1 and second relationship data indicating a relationship between impedance and SOH of cell stack 1; impedance calculation unit 8a that identifies a low current interval during which current flowing through secondary cells C0 to C7 is less than or equal to a threshold value, identifies a voltage obtained by voltage measurement unit 3 during the low current interval as a provisional OCV, and calculates an impedance of secondary cells C0 to C7 from the provisional OCV identified and from a voltage value obtained by voltage measurement unit 3 and a current value obtained by current measurement unit 4 in a transient current response; SOH estimate unit 9a that estimates the SOH of secondary cells C0 to C7 by referencing the second relationship data using the impedance obtained by impedance calculation unit 8a; and SOC estimate unit 9b that estimates the SOC of secondary cells C0 to C7 by referencing the first relationship data, based on the provisional OCV.

This enables the SOC and the SOH to be estimated by identifying a low current interval during which current flowing through secondary cells C0 through C7 is less than or equal to a threshold value and using a voltage of secondary cells C0 through C7 during the low current interval as a provisional OCV. Therefore, even in a case where the secondary cells are used in a state in which they are constantly being charged and discharged, the SOC and the SOH of the secondary cell can be accurately estimated. Since the SOH is estimated from the impedances of secondary cells C0 through C7 obtained from the transient response current, the SOH can be estimated by utilizing the timing of charging or discharging of cell stack 1 without requiring an AC signal source or the like needed for AC impedance measurement.

Here, SOC estimate unit 9b estimates an OCV of secondary cells C0 through C7 as a first OCV using the provisional OCV, the impedance obtained by impedance calculation unit 8a, and the current value obtained by current measurement unit 4 in the transient current response, and estimates the SOC of secondary cells C0 through C7 by referencing the first relationship data using the first OCV estimated. This enables the SOC of secondary cells C0 through C7 to be estimated using the first OCV corrected taking into consideration the voltage drop at the internal impedance of secondary cells C0 through C7 with respect to the provisional OCV, making it possible to estimate the SOC more accurately.

Battery monitoring device 20 further includes current integrate unit 8b that calculates an integrated value of current values obtained by current measurement unit 4. SOC estimate unit 9b references the first relationship data to identify, as an initial OCV, an OCV corresponding to an SOC obtained by subtracting the integrated value obtained by current integrate unit 8b from the SOC corresponding to the provisional OCV, and when the difference between the identified initial OCV and the first OCV is greater than or equal to a threshold value, updates the initial OCV in the first relationship data using the first OCV. This enables the first relationship data stored in storage 10 to be dynamically updated using an accurate first OCV, maintaining accurate SOC estimation.

When a state in which current values repeatedly obtained by current measurement unit 4 are (i) less than or equal to a threshold value and (ii) consistent within a predetermined range consecutively occurs a predetermined number of times or more, impedance calculation unit 8a identifies a duration that the state consecutively occurs as the low current interval. This enables the low current interval to be identified based on the number of times a low current is detected.

Alternatively, when current values repeatedly obtained by current measurement unit 4 remain less than or equal to a threshold value for a predetermined amount of time or longer, impedance calculation unit 8a identifies a duration during which the current values remain less than or equal to the threshold value as the low current interval. This enables the low current interval to be identified based on the duration during which a low current is detected.

The second relationship data indicates a relationship between Warburg impedance and SOH, impedance calculation unit 8a calculates a Warburg impedance of secondary cells C0 through C7, and SOH estimate unit 9a calculates a rate of increase of the Warburg impedance calculated by impedance calculation unit 8a with respect to a Warburg impedance of secondary cells C0 through C7 in an initial state that is obtained in advance, and estimates the SOH by referencing the second relationship data using the rate of increase calculated. This enables the SOH of secondary cells C0 through C7 to be estimated from the rate of increase of the Warburg impedance by referencing the second relationship data stored in storage 10, making it possible to estimate an accurate SOH in a simple manner.

Measurement unit 13 further includes temperature measurement unit 2 that measures a temperature of secondary cells C0 through C7, and impedance calculation unit 8a corrects the impedance calculated, using a temperature value obtained by temperature measurement unit 2. This enables the temperature dependence of the impedance of secondary cells C0 through C7 to be inhibited, making it possible to estimate a more accurate SOC and SOH.

Calculation unit 14 further includes communication unit 11 that outputs, to an external destination, at least the SOC estimated by SOC estimate unit 9b and the SOH estimated by SOH estimate unit 9a. This enables a higher-level system such as an AGV equipped with battery monitoring device 20 to obtain the SOC and the SOH of cell stack 1 through communication and utilize them for control and monitoring of the charging and discharging of cell stack 1, thereby inhibiting overcharging and overdischarging of cell stack 1 and making it possible to efficiently use cell stack 1 for a long time.

Communication unit 11 outputs data stored in storage 10 to external storage device 12, and receives data stored in external storage device 12 and stores the data in storage 10. This enables synchronizing data between storage 10 and external storage device 12, and maintaining high-precision battery state estimation by downloading and updating data in storage 10 according to the latest type of secondary cell.

Impedance calculation unit 8a identifies, as the low current interval, a duration during which current flowing through secondary cells C0 through C7 is 0.2 C or less. This enables obtaining a value close to the original OCV, that is, the terminal voltage of secondary cells C0 through C7 in an open circuit state, as the provisional OCV, making it possible to estimate an accurate SOC and SOH.

Hereinbefore, the battery monitoring device according to the present disclosure has been described based on embodiments, but the present disclosure is not limited to these embodiments. Various modifications to the present embodiment that may be conceived by those skilled in the art, as well as other embodiments resulting from combinations of some elements of the embodiment, are intended to be included within the scope of the present disclosure as long as these do not depart from the essence of the present disclosure.

For example, in the above embodiments, the SOC of cell Cn is estimated by referencing the first relationship data using the first OCV obtained by correcting the voltage drop at the internal impedance of cell Cn from the provisional OCV obtained in the low current interval, but when the current flowing in the low current interval is small, the SOC of cell Cn may be estimated by referencing the first relationship data using the provisional OCV.

In the above embodiments present example of identifying the low current interval using the number of investigations illustrated in FIG. 9 or using the investigation time illustrated in FIG. 10 are given, but the method is not limited to only one of these. For example, the low current interval may be identified by a combination of the C-rate for determining low current, the number of investigations, and the investigation time.

### INDUSTRIAL APPLICABILITY

The present disclosure can be utilized as a battery monitoring device that monitors the state of a cell stack including secondary cells such as lithium-ion secondary cells, particularly as a battery monitoring device capable of estimating the SOC and the SOH of the secondary cells even in a case where the secondary cells are used in a state in which they are constantly being charged and discharged, for example, as a battery monitoring device that monitors the state 10 of a cell stack equipped in an AGV, drone, cleaning robot, or the like.

1. A battery monitoring device that monitors a state of a cell stack including secondary cells connected in series or parallel, the battery monitoring device comprising:
a measurement unit configured to measure a state of the secondary cells; and
a calculation unit configured to calculate and estimate a state of charge (SOC) and a state of health (SOH) of the secondary cells based on the state of the secondary cells measured, wherein
the measurement unit includes:
a voltage measurement unit configured to measure a voltage of the secondary cells; and
a current measurement unit configured to measure current flowing through the secondary cells,
the calculation unit includes:
storage that holds at least first relationship data indicating a relationship between SOC and open circuit voltage (OCV) of the cell stack and second relationship data indicating a relationship between impedance and SOH of the cell stack;
an impedance calculation unit configured to identify a low current interval during which current flowing through the secondary cells is less than or equal to a threshold value, identify a voltage obtained by the voltage measurement unit during the low current interval as a provisional OCV, and calculate an impedance of the secondary cells from the provisional OCV identified and from a voltage value obtained by the voltage measurement unit and a current value obtained by the current measurement unit in a transient current response;
an SOH estimate unit configured to estimate the SOH of the secondary cells by referencing the second relationship data using the impedance obtained by the impedance calculation unit; and
an SOC estimate unit configured to estimate the SOC of the secondary cells by referencing the first relationship data, based on the provisional OCV.

2. The battery monitoring device according to claim 1, wherein
the SOC estimate unit is configured to estimate an OCV of the secondary cells as a first OCV using the provisional OCV, the impedance obtained by the impedance calculation unit, and the current value obtained by the current measurement unit in the transient current response, and estimate the SOC of the secondary cells by referencing the first relationship data using the first OCV estimated.

3. The battery monitoring device according to claim 2, further comprising:
a current integrate unit configured to calculate an integrated value of current values obtained by the current measurement unit, wherein
the SOC estimate unit is configured to reference the first relationship data to identify, as an initial OCV, an OCV corresponding to an SOC obtained by subtracting the integrated value obtained by the current integrate unit from an SOC corresponding to the provisional OCV, and when a difference between the initial OCV identified and the first OCV is greater than or equal to a threshold value, update the initial OCV in the first relationship data using the first OCV.

4. The battery monitoring device according to claim 1, wherein
when a state in which current values repeatedly obtained by the current measurement unit are (i) less than or equal to a threshold value and (ii) consistent within a predetermined range consecutively occurs a predetermined number of times or more, the impedance calculation unit is configured to identify a duration that the state consecutively occurs as the low current interval.

5. The battery monitoring device according to claim 1, wherein
when current values repeatedly obtained by the current measurement unit remain less than or equal to a threshold value for a predetermined amount of time or longer, the impedance calculation unit is configured to identify a duration during which the current values remain less than or equal to the threshold value as the low current interval.

6. The battery monitoring device according to claim 1, wherein
the second relationship data indicates a relationship between Warburg impedance and SOH,
the impedance calculation unit is configured to calculate a Warburg impedance of the secondary cells, and
the SOH estimate unit is configured to calculate a rate of increase of the Warburg impedance calculated by the impedance calculation unit with respect to a Warburg impedance of the secondary cells in an initial state that is obtained in advance, and estimate the SOH by referencing the second relationship data using the rate of increase calculated.

7. The battery monitoring device according to claim 1, wherein
the measurement unit further includes a temperature measurement unit configured to measure a temperature of the secondary cells, and
the impedance calculation unit is configured to correct the impedance calculated, using a temperature value obtained by the temperature measurement unit.

8. The battery monitoring device according to claim 1, wherein
the calculation unit further includes a communication unit configured to output, to an external destination, at least the SOC estimated by the SOC estimate unit and the SOH estimated by the SOH estimate unit.

9. The battery monitoring device according to claim 8, wherein
the communication unit is configured to output data stored in the storage to an external storage device, and receive data stored in the external storage device and stores the data in the storage.

10. The battery monitoring device according to claim 1, wherein
the impedance calculation unit is configured to identify, as the low current interval, a duration during which current flowing through the secondary cells is 0.2 C or less.
